(19) United States
(12) Patent Application Publication
(10) Pub. No.: US 2007/0217247 A1
(43) Pub. Date: Sep. 20, 2007

(54) Shared sense amplifier for fuse cell

(76) Inventors: Zhanping Chen, Portland, OR (US); Kevin Zhang, Portland, OR (US); Jonathan P. Douglas, Portland, OR (US); Praveen Mosalikanti, Hillsboro, OR (US); Gregory F. Taylor, Portland, OR (US)

Correspondence Address: SCHWABE, WILLIAMSON & WYATT, P.C., PACWEST CENTER, SUITE 1900, 1211 S.W. FIFTH AVE., PORTLAND, OR, 97204, US

(21) Appl. No.: 11/377,140

(22) Filed: Mar. 15, 2006

(51) Int. Cl. G11C 17/00; G11C 7/02

(52) U.S. Cl. 365/96; 365/208

(57) ABSTRACT

An apparatus, a method, and a system for a fuse array are disclosed herein. In some embodiments, fuse array may comprise a plurality of fuse cells and a single sense amplifier coupled to plurality of fuse cells to asynchronously sense one or more voltages output by the plurality of fuse cells, one fuse cell at a time.

### TECHNICAL FIELD

Embodiments of the invention relate generally to the field of integrated circuit design, specifically to methods, apparatuses, and systems associated with and/or having fuse cells.

### BACKGROUND

Microprocessor speed is ever-increasing to keep pace with consumer and competitive demands. In order to provide the volume of data required to productively exploit the increased speed, larger and larger caches are being incorporated into the new generation of microprocessors. In addition, due to the increasing cost of chip manufacturing, redundancies of the large caches, sometimes using fuse technology, are further incorporated to improve yield by replacing defective elements with spare elements.

Although larger cache with spare elements has the benefit of more effectively taking advantage of increased microprocessor speed, of particular concern with larger cache size and redundancy is the accompanying decrease in area-efficiency.

### BRIEF DESCRIPTION OF THE DRAWINGS

Embodiments of the present invention will be readily understood by the following detailed description in conjunction with the accompanying drawings. Embodiments of the invention are illustrated by way of example and not by way of limitation in the figures of the accompanying drawings.

FIG. 1 illustrates a fuse array incorporated with the teachings of the present invention, in accordance with various embodiments;

FIG. 2 illustrates a fuse cell incorporated with the teachings of the present invention, in accordance with various embodiments;

FIG. 3 illustrates another fuse cell incorporated with the teachings of the present invention, in accordance with various embodiments;

FIG. 4 illustrates another fuse cell incorporated with the teachings of the present invention, in accordance with various embodiments;

FIG. 5 illustrates another fuse cell incorporated with the teachings of the present invention, in accordance with various embodiments;

FIG. 6 illustrates a fuse block incorporated with the teachings of the present invention, in accordance with various embodiments; and

FIG. 7 illustrates a system incorporated with a fuse array in accordance with various embodiments of the present invention.

### DETAILED DESCRIPTION OF EMBODIMENTS OF THE INVENTION

In the following detailed description, reference is made to the accompanying drawings which form a part hereof wherein like numerals designate like parts throughout, and in which is shown by way of illustration embodiments in which the invention may be practiced. It is to be understood that other embodiments may be utilized and structural or logical changes may be made without departing from the scope of the present invention. Therefore, the following detailed description is not to be taken in a limiting sense, and the scope of embodiments in accordance with the present invention is defined by the appended claims and their equivalents.

Various operations may be described as multiple discrete operations in turn, in a manner that may be helpful in understanding embodiments of the present invention; however, the order of description should not be construed to imply that these operations are order dependent.

The description may use perspective-based descriptions such as up/down, back/front, and top/bottom. Such descriptions are merely used to facilitate the discussion and are not intended to restrict the application of embodiments of the present invention.

For the purposes of the present invention, the phrase “A/B” means A or B. For the purposes of the present invention, the phrase “A and/or B” means “(A), (B), or (A and B)”. For the purposes of the present invention, the phrase “at least one of A, B, and C” means “(A), (B), (C), (A and B), (A and C), (B and C), or (A, B and C)”. For the purposes of the present invention, the phrase “(A)B” means “(B) or (AB)” that is, A is an optional element.

The description may use the phrases “in an embodiment,” or “in embodiments,” which may each refer to one or more of the same or different embodiments. Furthermore, the terms “comprising,” “including,” “having,” and the like, as used with respect to embodiments of the present invention, are synonymous.

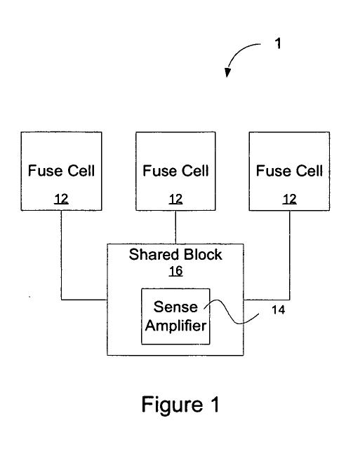

FIG. 1 illustrates a fuse array 1 in accordance with various embodiments of the present invention. In various ones of these embodiments, fuse array 1 may comprise a plurality of fuse cells 12 and a sense amplifier 14 coupled to the plurality of fuse cells 12. As shown, sense amplifier 14 may be part of a shared block 16 including various shared devices and/or circuitry (for example, high voltage protection circuitry to protect sense amplifier 14). In any case, plurality of fuse cells 12 may share sense amplifier 14. In some cases, sharing of sense amplifier 14 may vitiate or reduce the need for each fuse cell 12 to include its own dedicated sense amplifier 14. Thus, sharing sense amplifier 14 may realize, in some embodiments, an improved area-efficiency of an integrated circuit.

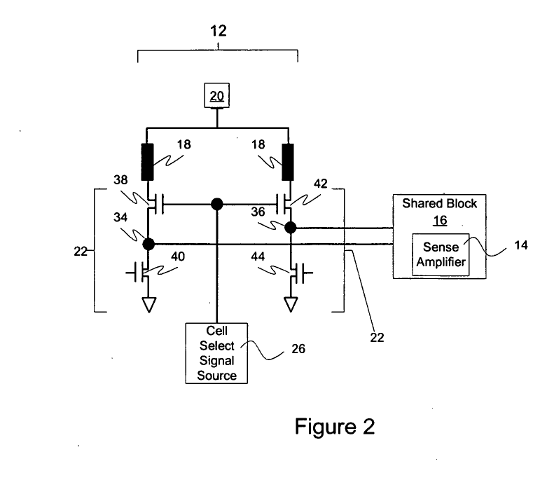

In various embodiments, plurality of fuse cells 12 may comprise one or more fuse devices 18. A fuse cell 12 in accordance with various embodiments of the present invention is shown in FIG. 2. Fuse devices 18 may be configured to output one or more voltages and, in some of these embodiments, one or more voltages may be sensed by sense amplifier 14 (discussed more fully below). Depending on the application, fuse devices 18 of fuse cell 12 may be coupled to a voltage source 20 to provide a voltage to fuse devices 18. In various ones of these embodiments, one or more of fuse devices 18 may receive voltage from voltage source 20, and output one or more voltages to sense amplifier 14.

In various embodiments, sense amplifier 14 may be variously formed and/or configured. For example, sense amplifier 14 may be a generic current mirror-based sense amplifier with one reference branch as a current source, and one or more current mirror branches as a repeater.

Depending on the application, sharing sense amplifier 14 may require scheduling of voltage output from plurality of fuse cells 12 in order for sense amplifier 14 to generate an accurate signal based on received voltage(s) from fuse cells 12. Put another way, sensing one fuse cell 12 at a time may be done in order to accurately read each fuse cell 12 because a sense amplifier 14 may not be able to parse through voltages to determine which fuse cell 12 output which voltage(s). Thus, in various embodiments, sense amplifier 14 may be coupled to plurality of fuse cells 12 to asynchronously sense one or more voltages output by plurality of fuse cells 12 so that one fuse cell 12 at a time may be selected for outputting voltage(s) to sense amplifier 14. For instance, a first of plurality of fuse cells 12 may be selected to output a first one or more voltages during a first time period, the first one or more voltage(s) being sensed by sense amplifier 14 and the unselected fuse cells 12 not outputting any voltage during the same first time period. Then, a second of plurality of fuse cells 12 may be selected to output a second one or more voltages during a second (different) time period, which is then sensed by sense amplifier 14 and the unselected fuse cells 12 not outputting any voltage during the second time period. A method in accordance with various embodiments of the present invention may continue these operations as necessary and/or desired.

Scheduling of voltage output from plurality of fuse cells 12 may comprise providing a cell select signal to one of plurality of fuse cells 12. In various ones of these embodiments, fuse array 1 may comprise cell select signal source 26, an embodiment of which is shown in FIG. 2. In various ones of these embodiments, cell select signal source 26 may be configured to selectively provide a cell select signal, for various purposes. For instance, in some embodiments, cell select signal may indicate to one or more fuse cells 12 that the fuse cell 12 is selected for sensing and/or programming. With respect to a sensing purpose, a cell select signal may indicate to one of plurality of fuse cells 12 to output voltage(s) for sensing by sense amplifier 14 and in some cases may comprise switching on one or more switchable conductive path devices 38, 40, 42, 44 of fuse cell 12. Methods in accordance with various embodiments may continue providing of cell select signal to one or more plurality of fuse cells 12, one or more at a time, depending on the application. Furthermore, in various embodiments, any number of fuse cells 12 may be incorporated into fuse array 1 and thus the previous steps may repeat accordingly.

With respect to fuse cells 12, fuse cells 12 may be variously configured in any manner known in the art. For instance, in various embodiments plurality of fuse cells 12 may comprise any number of fuse devices 18, depending on the application. An embodiment of a fuse cell 12 having two fuse devices 18 is shown in FIG. 2. Fuse cells 12 may be single-ended or double-ended fuse cells 12, also depending on the application. Further, fuse devices 18 of fuse cells 12 may be made from any material known in the art, including polysilicon and various metals. Again, fuse cells 12 may be variously formed and/or configured within the scope of the present invention.

Fuse array 1 may comprise a programming circuitry 22, depending on the application. In various ones of these embodiments, programming circuitry 22 may be coupled to one of the fuse cells 12 and configured to program one or more of fuse devices 18 of fuse cells 12. For instance, in various embodiments and as shown in FIG. 2, first programming circuitry 22 may be configured to program first fuse device 18 and second programming circuitry 22 may be configured to program second fuse device 18.

Still referring to programming circuitry 22, in various embodiments one or more of programming circuitry 22 may include one or more switchable conductive path devices 38, 40, 42, 44. Depending on the application, switchable conductive path devices 38, 40, 42, 44 may be arranged in serial or parallel. Further, switchable conductive path devices 38, 40, 42, 44 may be PMOS or NMOS devices. In some of these embodiments, one or more PMOS or NMOS devices may have different threshold voltages from other PMOS or NMOS devices of fuse cell 12. In various embodiments, serially-arranging switchable conductive path devices 38, 40, 42, 44 may accrue certain benefits, including, for example, increased tolerance to high voltages. A programming circuitry 22 comprising serially-arranged switchable conductive path devices 38, 40, 42, 44 is shown in FIG. 2. As shown and in accordance with various embodiments of the present invention, programming circuitry 22 may comprise two such switchable conductive path devices 38, 40, 42, 44. In various embodiments, sense amplifier 14 may be coupled to one or more nodes 34, 36 disposed between switchable conductive path devices 38, 40, 42, 44. As shown, for example, sense amplifier 14 may be coupled to a first node 34 disposed between switchable conductive path devices 38 and 40, and may be further coupled to a second node 36 disposed between switchable conductive path devices 42 and 44. In some embodiments, sense amplifier 14 may be coupled, via node 34, 36, to one or more of the plurality of fuse cells 12 to sense one or more voltages output by the plurality of fuse cells 12. Although one embodiment of programming circuitry 22 is shown in FIG. 2, other embodiments of programming circuitry 22 may be variously configured to suit any particular application yet still remain within the scope of this invention.

Fuse cell 12 may comprise other circuitry or devices in various embodiments in accordance with the present invention. In various embodiments, fuse cell 12 may comprise circuitry including, for example, any one or more of additional sense amplifier circuitry, high voltage protection circuitry, various control signal sources, one or more flip-flop circuits to store the sensed data from sense amplifier 14, etc. In alternate embodiments, other various circuitry devices and/or design topologies may be enlisted, depending on the desired use and function of fuse cell 12.

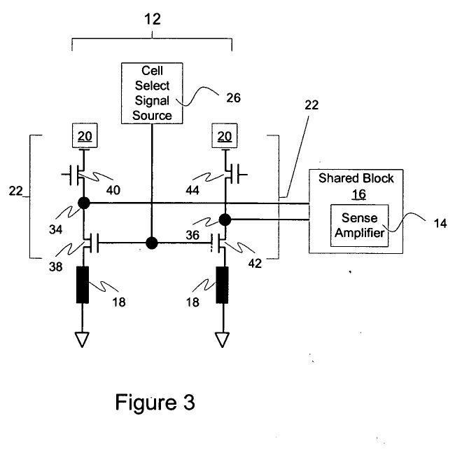

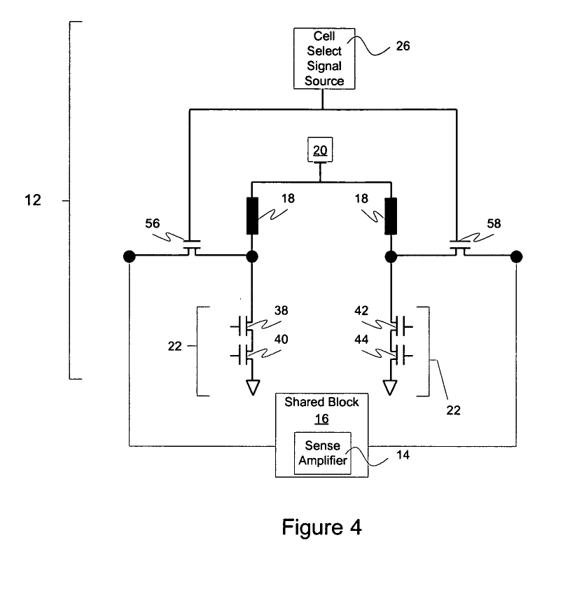

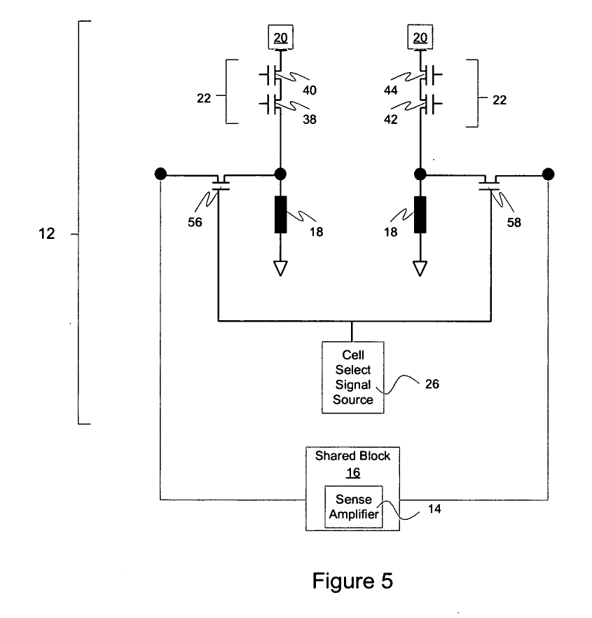

FIG. 3, FIG. 4, and FIG. 5 illustrate other embodiments of fuse cells 12 in accordance with various embodiments of the present invention. In various embodiments and as shown in FIG. 3, fuse cell 12 may comprise programming circuitry 22 configured to receive a supply voltage from one or more supply voltage sources 20. In yet another embodiment and as shown in FIG. 4, fuse cell 12 may comprise cell select signal source 26 which may be configured to provide a cell select signal to one or more switchable conductive path devices 56, 58. In various embodiments and as shown in FIG. 5, fuse cell 12 may comprise programming circuitry 22 configured to receive a supply voltage from one or more supply voltage sources 20.

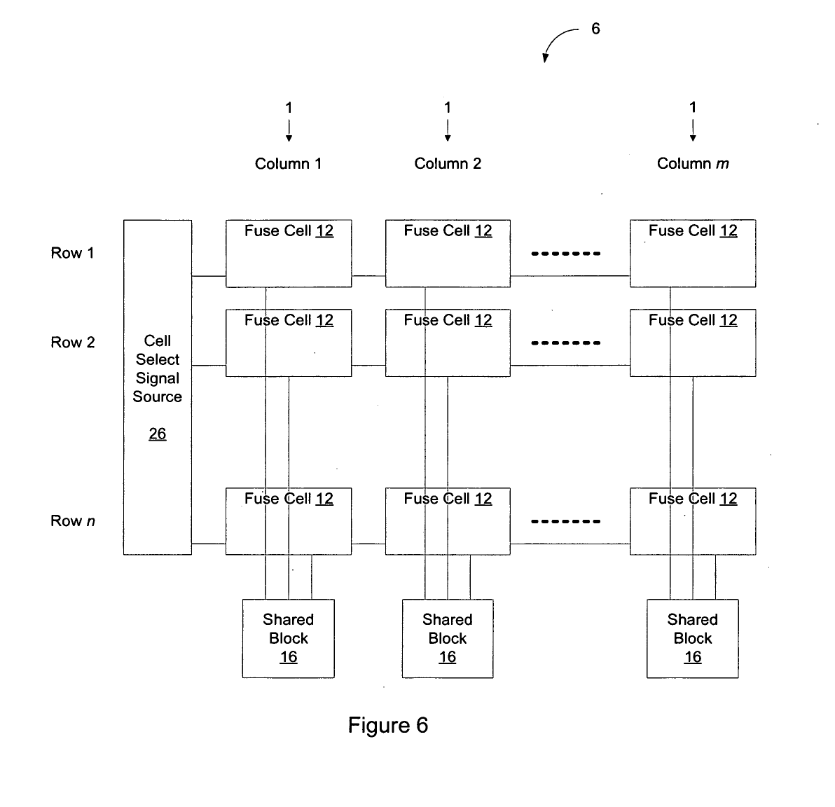

Illustrated in FIG. 6 is a fuse block 6 in accordance with various embodiments of the present invention. In addition to a single fuse array 1 discussed above, multiple fuse arrays 1 may be included in various embodiments of the present invention. In these embodiments, multiple fuse arrays 1 may form a fuse block 6. As shown, each additional fuse array 1 may comprise another plurality of fuse cells 12 and another sense amplifier 14 (shown as part of a shared block 16). As in the embodiments discussed previously, plurality of fuse cells 12 may have one or more fuse devices 18 configured to output another one or more voltages. Further, additional sense amplifiers 14 may be configured to asynchronously sense other one or more voltages output the additional plurality of fuse cells 12 to asynchronously sense the other one or more voltages output by the other plurality of fuse cells 12, one fuse cell 12 at a time.

Fuse blocks 6 incorporating fuse arrays 1 in accordance with the present invention may be variously configured. For instance, a fuse block 6 may incorporate different types of fuse cells 12, including, for example, single-ended and/or double-ended fuse cells 12. In embodiments in which both single-ended and double-ended fuse cells 12 are enlisted, single-ended fuse cells 12 and double-ended fuse cells 12 may be separated into different fuse arrays 1 within a fuse block 6 thereby using different sense amplifiers 14, i.e., each fuse array 1 comprises a single type of fuse cell 12, either single-ended fuse cells 12 or double-ended fuse cells 12. Further, in various embodiments, a fuse array 1 of fuse block 6 may have a different number of fuse cells 12 than other fuse arrays 1 in fuse block 6. However, in various other embodiments, all fuse arrays 1 within fuse block 6 may include the same number of fuse cells 12.

As shown in FIG. 6, fuse block 6 may comprise columns and rows. In some of these embodiments, a column may comprise fuse cells 12 coupled to a single sense amplifier 14, and a row may comprise fuse cells 12 wherein each fuse cell 12 is coupled to a different sense amplifier 14. In these embodiments, multiple fuse cells 12 in a row may be sensed by sense amplifier 14 simultaneously because fuse cells 12 of a row would each be coupled to a different sense amplifier 14. In various embodiments, fuse cells 12 of a row may be coupled to a single cell select signal source 26 and in these embodiments, a single cell select signal may indicate to a row of fuse cells 12 to output voltage(s) for sensing by sense amplifier 14. In other embodiments, other architectures of fuse arrays 1 and/or fuse block 6 may be variously configured depending on the application within the scope of the present invention.

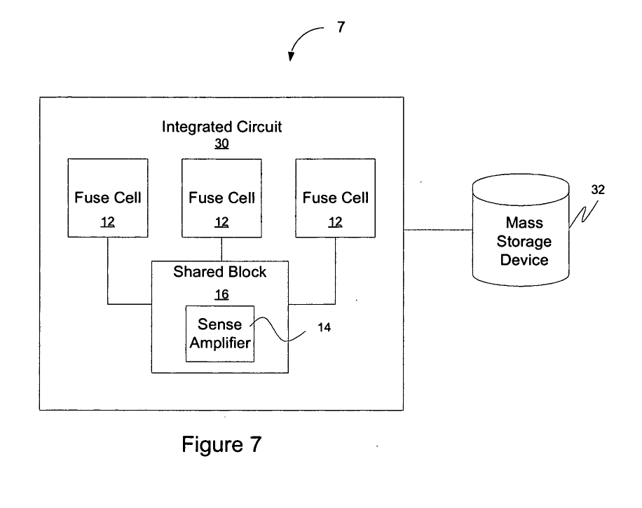

FIG. 7 illustrates a system 7 incorporating one or more fuse arrays 1 in accordance with various embodiments of the present invention. As shown, system 7 may comprise an integrated circuit 30 having a fuse array, and one or more mass storage devices 32 coupled to the integrated circuit 30. In various embodiments, integrated circuit 30 may be a microprocessors or an Application Specific Integrated Circuit (ASIC), and the fuse array may be a part of a relatively large cache embodied in integrated circuit 30. As discussed previously, fuse array may comprise a plurality of fuse cells 12 and a sense amplifier 14 coupled to plurality of fuse cells 12. In some of these embodiments, plurality of fuse cells 12 may be configured to output one or more voltages, and sense amplifier 14 may be configured to asynchronously sense the voltage output of fuse cells 12. Mass storage device 32 and integrated circuit 30, except for the novel fuse cells described herein, may represent a broad range of these elements known in the art. System 7 may be embodied in a broad range of form factors from servers, to desktop, laptop, tablet, and/or handheld. Further, system 7 may be endowed with various operating systems and/or applications to solve various computing and/or communication problems.

Although certain embodiments have been illustrated and described herein for purposes of description of the preferred embodiment, it will be appreciated by those of ordinary skill in the art that a wide variety of alternate and/or equivalent embodiments or implementations calculated to achieve the same purposes may be substituted for the embodiments shown and described without departing from the scope of the present invention. Those with skill in the art will readily appreciate that embodiments in accordance with the present invention may be implemented in a very wide variety of ways. This application is intended to cover any adaptations or variations of the embodiments discussed herein. Therefore, it is manifestly intended that embodiments in accordance with the present invention be limited only by the claims and the equivalents thereof.

1. An apparatus, comprising:
a plurality of fuse cells, each fuse cell having one or more fuse devices configured to output one or more voltages; and
a sense amplifier coupled to the plurality of fuse cells to asynchronously sense the one or more voltages output by the plurality of fuse cells, a subset of the fuse cells at a time, the subset of fuse cells being less than the number of fuse cells coupled to the sense amplifier.

2. The apparatus of claim 1, further comprising a cell select signal source coupled to the plurality of fuse cells to selectively provide a cell select signal to one subset of the fuse cells to output voltage(s) for sensing by the sense amplifier.

3. The apparatus of claim 1, further comprising one or more programming circuitries, each programming circuitry coupled to one of the fuse cells and configured to program one or more of the fuse devices of the fuse cells.

4. The apparatus of claim 3, wherein one or more of the programming circuitries include one or more serially-arranged switchable conductive path devices.

5. The apparatus of claim 4, wherein the one or more of the programming circuitries includes two switchable conductive path devices, and wherein the sense amplifier is coupled to a node disposed between the two switchable conductive path devices.

6. The apparatus of claim 4, wherein the one or more of the programming circuitries includes two switchable conductive path devices, and wherein one of the two switchable conductive path devices is coupled to a cell select signal source to receive a cell select signal from the cell select signal source to indicate to one of the fuse cells, the fuse cell is selected for a selected one of sensing and programming.

7. The apparatus of claim 6, wherein the one of the two switchable conductive path devices is configured to switch on when the one of the two switchable conductive path devices receives the cell select signal.

8. The apparatus of claim 1, wherein the plurality of fuse cells are either single-ended fuse cells or double-ended fuse cells.

9. The apparatus of claim 1, further comprising another plurality of fuse cells, wherein each of the other plurality of fuse cells has one or more fuse devices configured to output another one or more voltages, and the apparatus further comprising another sense amplifier coupled to the other plurality of fuse cells to asynchronously sense the other one or more voltages output by the other plurality of fuse cells, another subset of the fuse cells at a time, the other subset of the fuse cells being smaller than the number of other fuse cells coupled to the other sense amplifier.

10. A system, comprising:
an integrated circuit having a fuse array that includes:
a plurality of fuse cells each fuse cell having one or more fuse devices configured to output one or more voltages; and
a sense amplifier coupled to the plurality of fuse cells to asynchronously sense the one or more voltages output by the plurality of fuse cells, a subset of fuse cells at a time, the subset of fuse cells being smaller than the number of fuse cells coupled to the sense amplifier; and
one or more mass storage devices coupled to the integrated circuit.

11. The system of claim 10, further comprising a cell select signal source coupled to the plurality of fuse cells to selectively provide a cell select signal to one subset of the fuse cells to output voltage(s) for sensing by the sense amplifier.

12. The system of claim 10, further comprising a programming circuitry coupled to one of the fuse cells and configured to program one or more of the fuse devices of the fuse cell.

13. The system of claim 12, wherein the programming circuitry includes one or more serially-arranged switchable conductive path devices.

14. The system of claim 13, wherein the programming circuitry includes two switchable conductive path devices, and wherein the sense amplifier is coupled to a node disposed between the two switchable conductive path devices.

15. The system of claim 13, wherein the programming circuitry includes two switchable conductive path devices, and wherein one of the two switchable conductive path devices is coupled to a cell select signal source to receive a cell select signal from the cell select signal source to indicate to one of the fuse cells, the fuse cell is selected for a selected one of sensing and programming.

16. The system of claim 15, wherein the one of the two switchable conductive path devices is configured to switch on when the one of the two switchable conductive path devices receives the cell select signal.

17. The system of claim 10, wherein the plurality of fuse cells are either single-ended fuse cells or double-ended fuse cells.

18. The system of claim 14, further comprising another plurality of fuse cells, wherein each of the other plurality of fuse cells has one or more fuse devices configured to output another one or more voltages, and the apparatus further comprising another sense amplifier coupled to the other plurality of fuse cells to asynchronously sense the other one or more voltages output by the other plurality of fuse cells, another subset of fuse cells at a time, the other subset of the fuse cells being smaller than the number of other fuse cells coupled to the other sense amplifier.

19. A method, comprising:
selecting a first of a plurality of fuse cells to output a first one or more voltages;
sensing the first one or more voltages using a sense amplifier coupled to all the fuse cells, the unselected one(s) of fuse cells not outputting any voltage;
selecting a second of the plurality of fuse cells to output a second one or more voltages; and
sensing the second one or more voltages using the same sense amplifier, the unselected one(s) of fuse cells not outputting any voltage.

20. The method of claim 19, further comprising providing a cell select signal to one of the fuse cells to output voltage(s) for sensing by the sense amplifier.

21. The method of claim 20, wherein providing a cell select signal to one of the fuse cells comprises switching on a switchable conductive path device of the fuse cell.

22. The method of claim 19, wherein selecting a second of the plurality of fuse cells to output second one or more voltages comprises selecting a reference fuse of the plurality of fuse cells to output a reference voltage.
